(19) United States
(12) Patent Application Publication
(10) Pub. No.: US 2025/0210418 A1
(43) Pub. Date: Jun. 26, 2025

(54) SEMICONDUCTOR PACKAGE AND PACKAGE MODULE INCLUDING THE SAME

(71) Applicant: SAMSUNG ELECTRONICS CO., LTD., Suwon-si (KR)

(72) Inventor: Yongmin YOO, Suwon-si (KR)

(73) Assignee: SAMSUNG ELECTRONICS CO., LTD., Suwon-si (KR)

(21) Appl. No.: 18/946,505

(22) Filed: Nov. 13, 2024

(30) Foreign Application Priority Data
Dec. 22, 2023 (KR) 10-2023-0190079

(51) Int. Cl. H01L 21/66; H01L 23/31; H01L 23/495

(52) U.S. Cl. CPC H01L 22/32; H01L 23/3185; H01L 23/49572

(57) ABSTRACT

A semiconductor package includes a film substrate, a plurality of first connection patterns and a plurality of second connection patterns disposed in a first direction on the film substrate, a semiconductor chip between the first and second connection patterns, a protection pattern on the film substrate and at least partially surrounding the semiconductor chip, a plurality of pads between the film substrate and the semiconductor chip, a test pattern between the film substrate and the protection pattern, a plurality of first lines respectively coupled with the plurality of first connection patterns, a plurality of second lines respectively coupled with the plurality of second connection patterns, and a test line extending from a second line of the plurality of second lines and coupled with the test pattern. The test line includes a first part coupled with the second line, and a second part coupling the first part with the test pattern.

### CROSS-REFERENCE TO RELATED APPLICATIONS

This application claims benefit of priority under 35 U.S.C § 119 to Korean Patent Application No. 10-2023-0190079, filed on Dec. 22, 2023, in the Korean Intellectual Property Office, the disclosure of which is incorporated by reference herein in its entirety.

### BACKGROUND

### 1. Field

The present disclosure relates generally to a semiconductor package, and more particularly, to a semiconductor package including a test line.

### 2. Description of Related Art

A chip-on-film (COF) package technique may refer to the use of a flexible film substrate to potentially address recent demand for smaller, thinner, and/or lighter electronic products. According to the COF package technique, a semiconductor chip may be directly flip-chip bonded to a film substrate and coupled through a short lead to an external circuit. The COF package may be applied to portable terminal devices such as, but not limited to, a cellular phone, a personal digital assistant (PDA), laptop computers, display panels, or the like.

### SUMMARY

One or more example embodiments of the present disclosure provide a semiconductor package with improved electrical properties, when compared with related semiconductor packages.

According to an aspect of the present disclosure, a semiconductor package includes a film substrate, a plurality of first connection patterns disposed in a first direction on the film substrate, a plurality of second connection patterns disposed in the first direction on the film substrate, a semiconductor chip between the plurality of first connection patterns and the plurality of second connection patterns, a protection pattern on the film substrate and at least partially surrounding the semiconductor chip, a plurality of pads between the film substrate and the semiconductor chip, a test pattern between the film substrate and the protection pattern, a plurality of first lines respectively coupled with the plurality of first connection patterns, a plurality of second lines respectively coupled with the plurality of second connection patterns, and a test line extending from a line of the plurality of second lines and coupled with the test pattern. The test line includes a first part between the film substrate and the semiconductor chip, and a second part coupling the first part with the test pattern. The first part of the test line being coupled with the line of the plurality of second lines.

According to an aspect of the present disclosure, a semiconductor package includes a film substrate including a plurality of sprocket holes, a plurality of first connection patterns disposed in a first direction on the film substrate, a plurality of second connection patterns disposed in the first direction on the film substrate, a semiconductor chip between the plurality of first connection patterns and the plurality of second connection patterns, a protection pattern on the film substrate and at least partially surrounding the semiconductor chip, a plurality of pads between the film substrate and the semiconductor chip, a test pattern between the film substrate and the protection pattern, a plurality of first lines respectively coupled with the plurality of first connection patterns, a plurality of second lines respectively coupled with the plurality of second connection patterns, and a test line extending from a line of the plurality of second lines and coupled with the test pattern. The test line is coupled with the line of the plurality of second lines between the film substrate and the semiconductor chip, and the test pattern between the film substrate and the protection pattern. The plurality of sprocket holes are aligned along a second direction that intersects the first direction.

According to an aspect of the present disclosure, a package module includes a circuit substrate, a display panel spaced apart from the circuit substrate, and a plurality of semiconductor packages between the circuit substrate and the display panel, the plurality of semiconductor packages electrically coupling the circuit substrate with the display panel. Each package of the plurality of semiconductor packages includes a film substrate including a sprocket hole, a first connection pattern coupled with the circuit substrate, a second connection pattern coupled with the display panel, a semiconductor chip on the film substrate, a protection pattern on the film substrate and at least partially surrounding the semiconductor chip, a plurality of pads between the film substrate and the semiconductor chip, a test pattern between the film substrate and the protection pattern, a first line coupled with the first connection pattern, a second line coupled with the second connection pattern, and a test line extending from the second line and coupled with the test pattern. The test line includes a first part at least partially overlapping the semiconductor chip, and a second part between the first line and the second line. The first line and the second line are adjacent to each other.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1A illustrates a plan view showing a semiconductor package, according to an embodiment;

FIG. 1B illustrates an enlarged view showing section E1 of FIG. 1A, according to an embodiment;

FIG. 1C illustrates an enlarged view showing section E2 of FIG. 1B, according to an embodiment;

FIG. 2 illustrates an enlarged plan view showing a semiconductor package, according to an embodiment;

FIG. 3 illustrates an enlarged plan view showing a semiconductor package, according to an embodiment;

FIG. 4 illustrates a plan view showing a semiconductor package, according to an embodiment;

FIG. 5A illustrates a plan view showing a semiconductor package, according to an embodiment; and

FIG. 5B illustrates a plan view showing a package module, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

A semiconductor package and a package module according to various embodiments of the present disclosure are described with reference to the accompanying drawings.

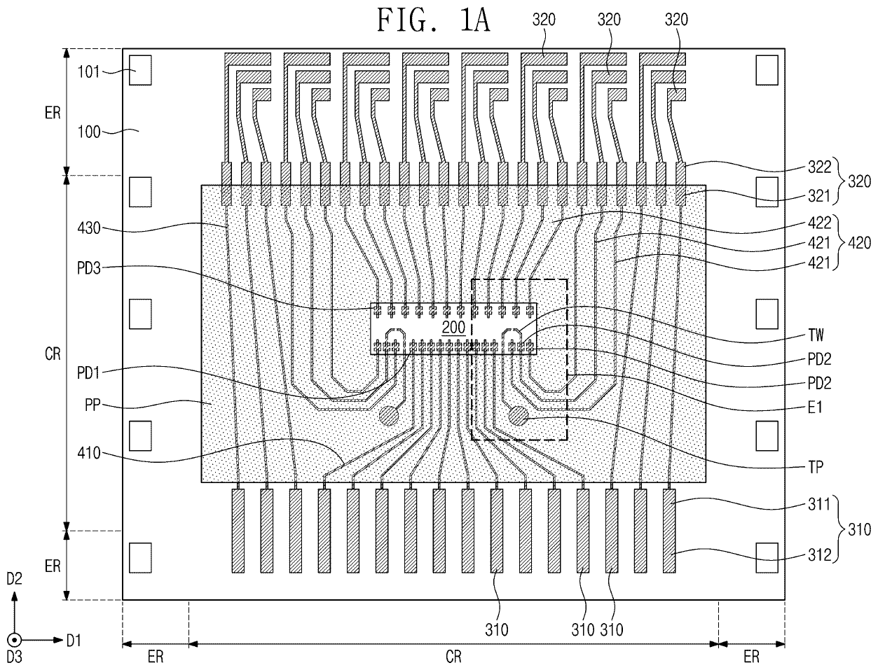

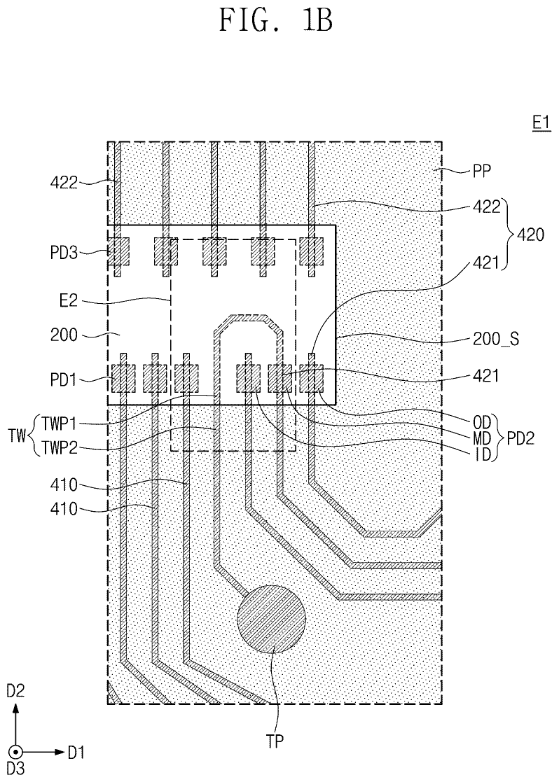

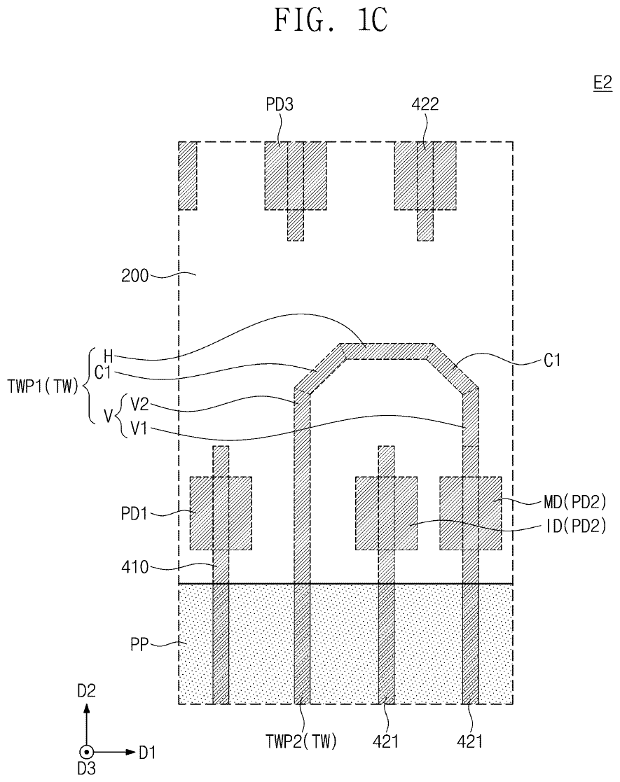

FIG. 1A illustrates a plan view showing a semiconductor package, according to an embodiment. FIG. 1B illustrates an enlarged view showing section E1 of FIG. 1A, according to an embodiment. FIG. 1C illustrates an enlarged view showing section E2 of FIG. 1B, according to an embodiment.

Referring to FIGS. 1A, 1B, and 1C, a semiconductor package may include a film substrate 100, a semiconductor chip 200, a plurality of first connection patterns 310, a plurality of second connection patterns 320, a plurality of first pads PD1, a plurality of second pads PD2, a plurality of third pads PD3, a plurality of first lines 410, a plurality of second lines 420, a plurality of third lines 430, a protection pattern PP, a test line TW, and a test pattern TP.

The film substrate 100 may be provided. The film substrate 100 may be and/or may include a base film on which are provided the semiconductor chip 200, the plurality of first connection patterns 310, the plurality of second connection patterns 320, the plurality of first pads PD1, the plurality of second pads PD2, the plurality of third pads PD3, the plurality of first lines 410, the plurality of second lines 420, the plurality of third lines 430, the protection pattern PP, the test line TW, and the test pattern TP. The film substrate 100 may have a plate shape that may extend along a plane elongated in a first direction D1 and a second direction D2. The first direction D1 and the second direction D2 may intersect each other. For example, the first direction D1 and the second direction D2 may be horizontal directions that are orthogonal to each other.

The film substrate 100 may include a polymeric material. For example, the film substrate 100 may include, but not be limited to, a polyimide. The film substrate 100 may be and/or may include a flexible soft substrate. That is, the film substrate 100 may be bendable. The film substrate 100 may include a chip region CR and an edge region ER. For example, the chip region CR may be an area on which the semiconductor chip 200 is mounted, and the edge region ER may be an area that surrounds the chip region CR.

The film substrate 100 may include a plurality of sprocket holes 101. When viewed in a plan view, the sprocket holes 101 may be disposed on the edge region ER of the film substrate 100. The sprocket holes 101 may be arranged along the second direction D2. The sprocket holes 101 may penetrate the film substrate 100. The sprocket holes 101 may be used to wind and/or unwind the semiconductor package.

The semiconductor chip 200 may be provided on the chip region CR of the film substrate 100. The semiconductor chip 200 may have a top surface and a bottom surface that are opposite to each other. The semiconductor chip 200 may include the plurality of first pads PD1, the plurality of second pads PD2, and the plurality of third pads PD3 on the bottom surface of the semiconductor chip 200. The plurality of first pads PD1 may be disposed spaced apart from each other along the first direction D1. The plurality of second pads PD2 may be disposed spaced apart from each other along the first direction D1. The plurality of third pads PD3 may be disposed spaced apart from each other along the first direction D1. The plurality of first pads PD1 may be disposed between the second pads PD2. The plurality of third pads PD3 may be spaced apart in the second direction D2 from the plurality of first pads PD1 and the plurality of second pads PD2.

The pluralities of first to third pads PD1 to PD3 may overlap in a third direction D3 with the semiconductor chip 200. The third direction D3 may intersect the first direction D1 and the second direction D2. For example, the third direction D3 may be a vertical direction perpendicular to the first direction D1 and the second direction D2.

The pluralities of first to third pads PD1 to PD3 may include a conductive material. For example, the pluralities of first to third pads PD1 to PD3 may include, but not be limited to, a metal. The pluralities of first to third pads PD1 to PD3 may be connected to an integrated circuit of the semiconductor chip 200 to transfer input signals and/or output signals. For example, the plurality of first pads PD1 may transfer input signals, and the pluralities of second and third pads PD2 and PD3 may transfer output signals. However, the present disclosure is not limited in this regard. For example, in an embodiment, the pluralities of first and second pads PD1 and PD2 may transfer input signals, and the plurality of third pads PD3 may transfer output signals.

The semiconductor chip 200 may be and/or may include, for example, a display driver integrated circuit (IC) that may drive a display panel. For example, the semiconductor chip 200 may generate image signals by using data signals transferred from a timing controller, and may output the image signals to the display panel. In some embodiments, the semiconductor chip 200 may be and/or may include a timing controller connected to a display driver IC.

Although FIG. 1A depicts one semiconductor chip 200, the number of the semiconductor chips 200 may not be limited to that shown. For example, the number of the semiconductor chips 200 may be two (2) or more.

The plurality of first connection patterns 310 and the plurality of second connection patterns 320 may be provided on the film substrate 100. Each of the plurality of first connection patterns 310 may include a first connection part 311 and a first cut part 312. The first connection part 311 may be provided on the chip region CR of the film substrate 100. The first cut part 312 may be provided on the edge region ER of the film substrate 100. The plurality of first connection patterns 310 may be arranged spaced apart from each other in the first direction D1. The plurality of first connection patterns 310 may be spaced apart from the protection pattern PP. In some embodiments, the plurality of first connection patterns 310 may be in contact with the protection pattern PP.

Each of the plurality of second connection patterns 320 may include a second connection part 321 and a second cut part 322. The second connection parts 321 of the plurality of second connection patterns 320 may be provided on the chip region CR of the film substrate 100. The second cut parts 322 of the plurality of second connection patterns 320 may be provided on the edge region ER of the film substrate 100. The plurality of second connection patterns 320 may be arranged spaced apart from each other in the first direction D1. The second connection parts 321 of the plurality of second connection pattern 320 may be in contact with the protection pattern PP. In some embodiments, the second connection parts 321 of the plurality of second connection patterns 320 may be spaced apart from the protection pattern PP.

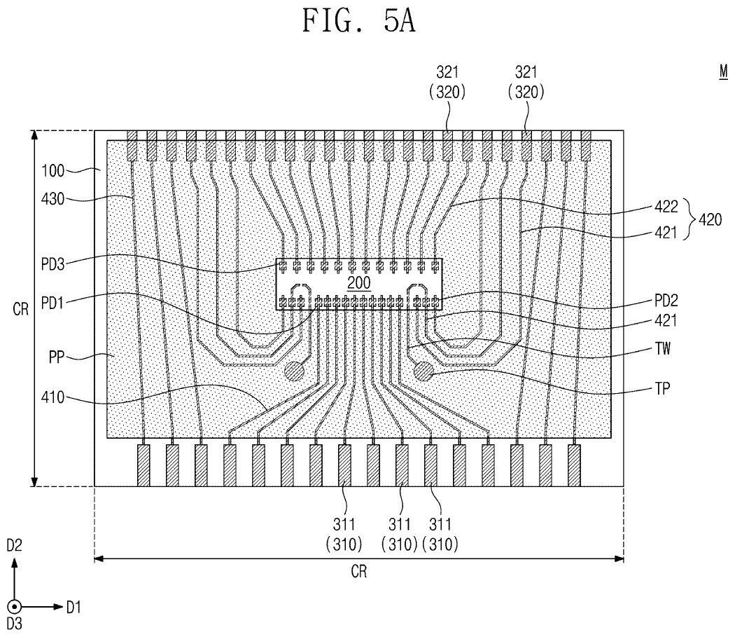

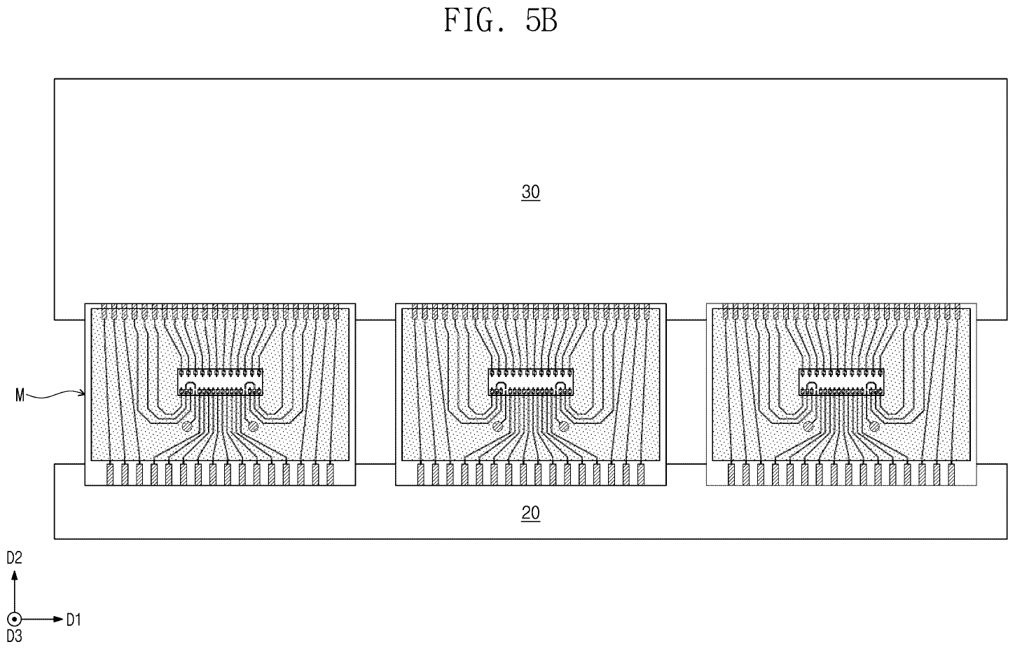

The edge region ER of the film substrate 100 may be removed to form a package module as described with reference to FIGS. 5A and 5B. The removal of the edge region ER of the film substrate 100 may include cutting the plurality of first connection patterns 310 and the plurality of second connection patterns 320 at a boundary between the edge region ER and the chip region CR, and removing the first cut parts 312 of the plurality of first connection patterns 310 and the second cut parts 322 of the plurality of second connection patterns 320.

The plurality of first connection patterns 310 and the plurality of second connection patterns 320 may be spaced apart in the second direction D2 from each other across the semiconductor chip 200. The plurality of first connection patterns 310 and the plurality of second connection patterns 320 may include a conductive material. For example, the plurality of first connection patterns 310 and the plurality of second connection patterns 320 may include, but not be limited to, a metal.

The pluralities of first to third lines 410 to 430 may be provided on the film substrate 100. The pluralities of first to third lines 410 to 430 may be spaced apart from each other.

The plurality of first lines 410 may connect the plurality of first pads PD1 to the plurality of first connection patterns 310. The plurality of first lines 410 may electrically connect the semiconductor chip 200 to the first connection parts 311 of the plurality of first connection patterns 310. The plurality of first lines 410 may be spaced apart from each other along the first direction D1. An interval between the first lines 410 may increase with increasing distance from the semiconductor chip 200.

The plurality of second lines 420 may connect the plurality of second pads PD2 to the plurality of second connection patterns 320 and/or may connect the plurality of third pads PD3 to the plurality of second connection patterns 320. The plurality of second lines 420 may electrically connect the semiconductor chip 200 to the plurality of second connection patterns 320. The plurality of second lines 420 may include first output lines 421 and second output lines 422. The first output lines 421 may connect the plurality of second pads PD2 to the second connection parts 321 of the plurality of second connection patterns 320. The second output lines 422 may connect the plurality of third pads PD3 to the second connection parts 321 of the plurality of second connection patterns 320. The second output lines 422 may have a length greater than that of the first output lines 421. The first output lines 421 may be disposed between the second output lines 422.

The plurality of third lines 430 may connect the plurality of first connection patterns 310 to the plurality of second connection patterns 320. The plurality of third lines 430 may be in contact with the first connection parts 311 of the plurality of first connection patterns 310 and with the second connection parts 321 of the plurality of second connection pattern 320. The third lines 430 may be spaced apart from each other along the first direction D1.

The pluralities of first to third lines 410 to 430 may include a conductive material. For example, the pluralities of first to third lines 410 to 430 may include, but not be limited to, a metal. The pluralities of first to third lines 410 to 430 may be provided in various shapes based on an arrangement of the plurality of first connection patterns 310 and the plurality of second connection patterns 320, a size of the semiconductor chip 200, and an arrangement of the pluralities of first to third pads PD1 to PD3.

The test pattern TP may be provided on the film substrate 100. The test pattern TP may be disposed between the film substrate 100 and the protection pattern PP. The test pattern TP may overlap in the third direction D3 with the film substrate 100 and the protection pattern PP. The test pattern TP may be in contact with the test line TW. The test pattern TP may be electrically connected to the test line TW. The test pattern TP may face the first line 410, the first output lines 421, and the third lines 430. The test pattern TP may be disposed between a first line 410 and a first output line 421 that are adjacent to each other. The test pattern TP may include a conductive material. For example, the test pattern TP may include, but not be limited to, copper (Cu). The test pattern TP may be used to test properties of the semiconductor chip 200. A measurement apparatus, which may include a probe, may be used to test properties of the semiconductor chip 200. The probe of the measurement apparatus may be allowed to contact the test pattern TP, and thus properties of the semiconductor chip 200 may be tested.

The test pattern TP may include a conductive material. For example, the test pattern TP may include, but not be limited to, a metal.

The test pattern TP may include a plurality of test patterns TP. For example, two (2) test patterns TP may be disposed symmetrically with each other across the first lines 410. The present disclosure, however, is not limited thereto, and no limitation may be imposed on the number of the test patterns TP. For example, the number of the test patterns TP may be one (1) or three (3) or more.

The protection pattern PP may be provided on the chip region CR of the film substrate 100. When viewed in a plan view, the protection pattern PP may surround the semiconductor chip 200. The protection pattern PP may be disposed on the first to third lines 410 to 430, the test line TW, and the test pattern TP. The protection pattern PP may cover the first to third lines 410 to 430, a portion of the test line TW, and the test pattern TP. The protection pattern PP may expose the first and second connection patterns 310 and 320. The protection pattern PP may include a dielectric material. For example, the protection pattern PP may include, but not limited to, a solder resist material. The protection pattern PP may protect the first to third lines 410 to 430, the test line TW, and the test pattern TP. For example, the protection pattern PP may protect the first to third lines 410 to 430, the test line TW, and the test pattern TP against oxidation and/or short-circuit that may occur in an annealing process.

The plurality of second pads PD2 may include an inner pad ID, an extension pad MD, and an outer pad OD. The inner pad ID may be adjacent to the first pad PD1. The extension pad MD may be disposed between the inner pad ID and the outer pad OD. The outer pad OD may be adjacent to a sidewall 200_S of the semiconductor chip 200.

The test line TW may be provided on the film substrate 100. The test line TW may connect the second line 420 to the test pattern TP. The test line TW may include a conductive material. For example, the test line TW may include, but not be limited to, a metal.

The test line TW may include a first part TWP1 and a second part TWP2. The first part TWP1 of the test line TW may be provided between the film substrate 100 and the semiconductor chip 200. The first part TWP1 may overlap the semiconductor chip 200. The first part TWP1 may not overlap the protection pattern PP. The first part TWP1 may have a loop shape. The first part TWP1 may have a loop shape whose bottom side is opened. The inner pad ID may have three (3) sides that may face the first part TWP1.

The second part TWP2 of the test line TW may be provided between the film substrate 100 and the protection pattern PP. The second part TWP2 may overlap the protection pattern PP. The second part TWP2 may not overlap the semiconductor chip 200. The second part TWP2 may be disposed between a first line 410 and a first output line 421 that are adjacent to each other. The first output line 421 adjacent to the first line 410 may be in contact with the extension pad MD. The second part TWP2 may connect the first part TWP1 to the test pattern TP.

The first part TWP1 of the test line TW may include a first straight portion H, second straight portions V, and corner portions C1. The first straight portion H may extend in the first direction D1. The second straight portion V may extend in the second direction D2. The corner portion C1 may connect the first straight portion H to the second straight portion V.

The first straight portion H of the first part TWP1 may connect the corner portions C1 to each other. The first straight portion H of the first part TWP1 may be disposed between the second pad PD2 and the third pad PD3. For example, the first straight portion H of the first part TWP1 may be disposed between the inner pad ID and the third pad PD3.

The second straight portions V of the first part TWP1 may include a first connection segment V1 and a second connection segment V2. The first connection segment V1 may connect the corner portion C1 to one of the first output lines 421. The one of the first output lines 421 that is connected to the first connection segment V1 may be in contact with the extension pad MD. The second connection segment V2 may connect the second part TWP2 to the corner portion C1. The second connection segment V2 may be disposed between the first pad PD1 and the inner pad ID. The second connection segment V2 may extend in the second direction D2 between the first pad PD1 and the inner pad ID.

The corner portion C1 of the first part TWP1 may connect the first straight portion H to the first connection segment V1 or may connect the first straight portion H to the second connection segment V2. The corner portions C1 may have straight shapes. In some embodiments, the corner portions C1 may be curved.

The test line TW may not be in contact with any of the first to third pads PD1 to PD3. The test line TW may not overlap any of the first to third pads PD1 to PD3. A distance between the first pad PD1 and the inner pad ID may be greater than a distance between the inner pad ID and the extension pad MD and/or a distance between the extension pad MD and the outer pad OD.

The present disclosure, however, is not limited thereto, and the test line TW may be provided in various shapes based on an arrangement of the pluralities of first and second connection patterns 310 and 320, a size of the semiconductor chip 200, and an arrangement of the pluralities of first to third pads PD1 to PD3, the pluralities of first to third lines 410 to 430, and the test pattern TP.

In the semiconductor package, according to some embodiments of the present disclosure, the test pattern TP may be disposed between a first line 410 and a first output line 421 that are adjacent to each other, and thus the test pattern TP may be separated to an outside. As the test pattern TP is separated, the test line TW may extend long between the film substrate 100 and the semiconductor chip 200 to come into connection with the test pattern TP. Thus, it may be possible to alleviate electromagnetic interference (EMI) and/or electrostatic discharge (ESD) and to improve electrical properties of the semiconductor package, when compared to related semiconductor packages.

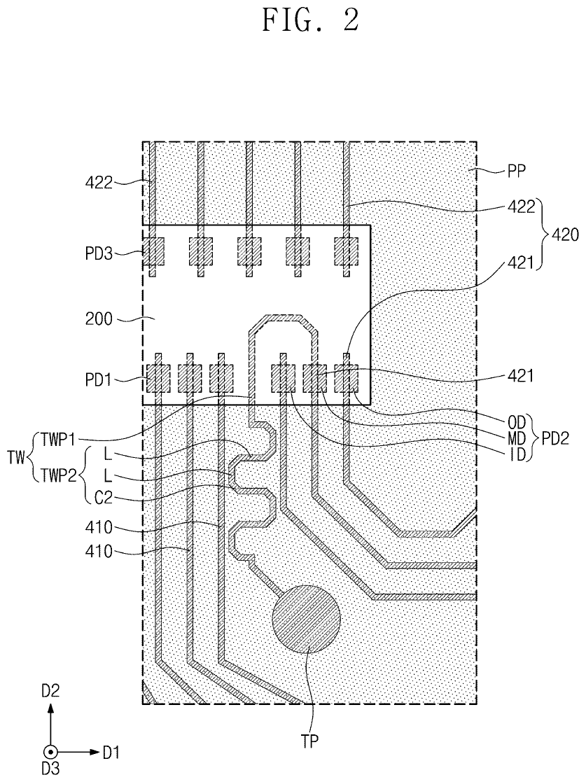

FIG. 2 illustrates an enlarged plan view showing a semiconductor package, according to some embodiments. The semiconductor package of FIG. 2 may include and/or may be similar in many respects to the semiconductor package described above with reference to FIGS. 1A to 1C, and may include additional features not mentioned above. Consequently, repeated descriptions of the semiconductor package described above with reference to FIGS. 1A to 1C may be omitted for the sake of brevity.

Referring to FIG. 2, the second part TWP2 may have a crooked shape between the first line 410 and the first output line 421 that are adjacent to each other.

The second part TWP2 may include straight portions L and corner portions C2. The straight portions L may extend in the first direction D1 or the second direction D2. The corner portions C2 may extend in a direction that intersects the first direction D1 and the second direction D2. The corner portion C2 may connect the straight portion L that extends in the first direction D1 to the straight portion L that extends in the second direction D2.

The present disclosure, however, is not limited thereto, and the second part TWP2 of the test pattern TP may bend or extend without limitation of direction or length.

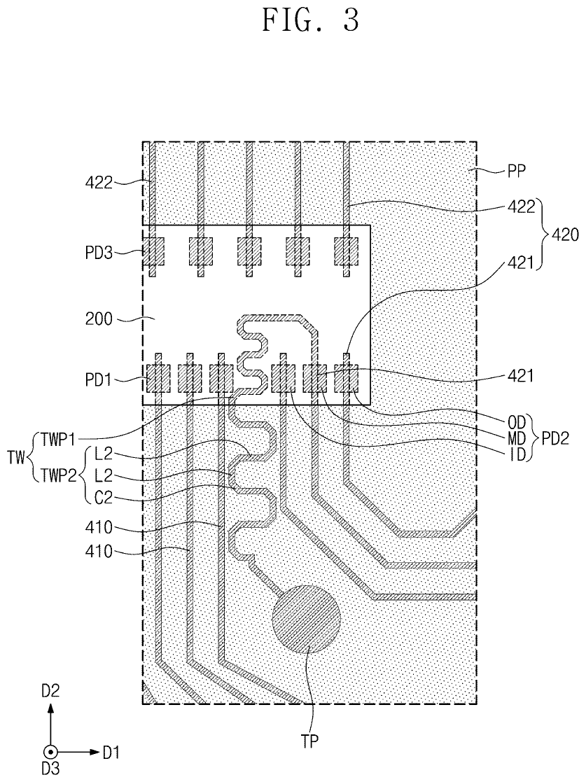

FIG. 3 illustrates an enlarged plan view showing a semiconductor package according to some embodiments. The semiconductor package of FIG. 3 may include and/or may be similar in many respects to the semiconductor package described above with reference to FIGS. 1A to 1C and 2, and may include additional features not mentioned above. Consequently, repeated descriptions of the semiconductor package described above with reference to FIGS. 1A to 1C and 2 may be omitted for the sake of brevity.

Referring to FIG. 3, the first part TWP1 may have a crooked shape between the first pad PD1 and the inner pad ID. The first part TWP1 may have a crooked shape between the second pad PD2 and the third pad PD3. In some embodiments, the first part TWP1 may have a crooked shape between the first pad PD1 and the third pad PD3.

The present disclosure, however, is not limited thereto, and the first part TWP1 of the test pattern TP may bend and/or extend without limitation between the film substrate 100 and the semiconductor chip 200.

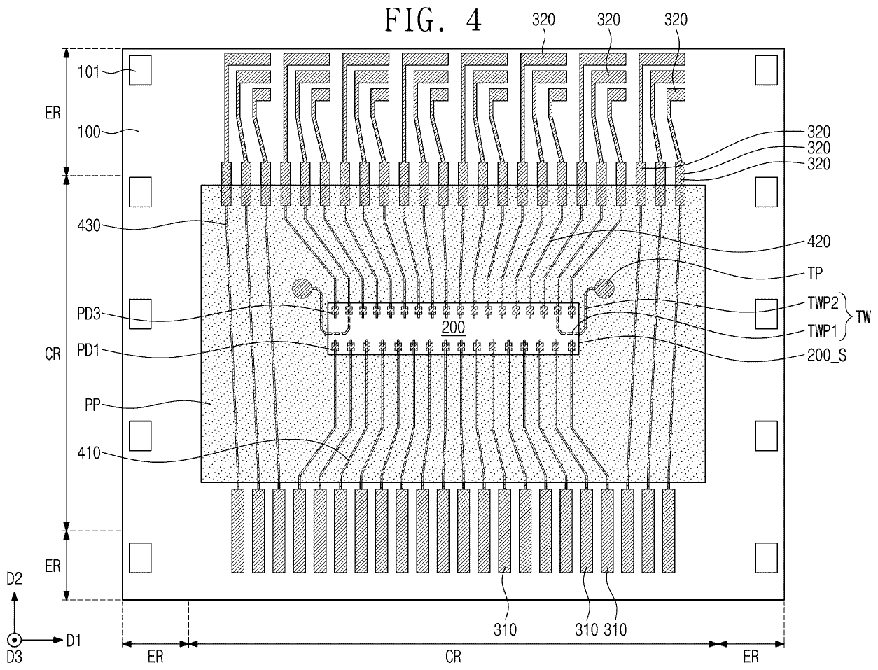

FIG. 4 illustrates a plan view showing a semiconductor package according to some embodiments. The semiconductor package of FIG. 4 may include and/or may be similar in many respects to the semiconductor package described above with reference to FIGS. 1A to 3, and may include additional features not mentioned above. Consequently, repeated descriptions of the semiconductor package described above with reference to FIGS. 1A to 3 may be omitted for the sake of brevity.

Referring to FIG. 4, a semiconductor package may not include the second pad PD2. The plurality of second lines 420 may be in contact with the plurality of third pads PD3. The plurality of second lines 420 may connect the plurality of third pads PD3 to the plurality of second connection patterns 320.

The test line TW may include a first part TWP1 and a second part TWP2. The first part TWP1 and the second part TWP2 may be distinguished across a sidewall 200_S of the semiconductor chip 200. The first part TWP1 may overlap the semiconductor chip 200. The second part TWP2 may not overlap the semiconductor chip 200.

The first part TWP1 may be disposed between the first pad PD1 and the third pad PD3. The first part TWP1 may be connected to one of the plurality of second lines 420. The first part TWP1 may extend from the one of the plurality of second lines 420 to bend toward the sidewall 200_S of the semiconductor chip 200.

The second part TWP2 may be disposed between a second line 420 and a third line 430 that are adjacent to each other. The second part TWP2 may be spaced apart from the second line 420 and the third line 430.

The test pattern TP may be disposed between the second line 420 and the third line 430 that are adjacent to each other. The test pattern TP may face the second line 420 and the third line 430 that are adjacent to each other.

The present disclosure, however, is not limited thereto, and the test pattern TP may be freely disposed between the first line 410, the second line 420, and the third line 430 that are adjacent to each other on the chip region CR. Therefore, the test line TW may bend and/or extend without limitation on the film substrate 100 to come into connection with the test pattern TP.

FIG. 5A illustrates a plan view showing a semiconductor package according to some embodiments. FIG. 5B illustrates a plan view showing a package module according to some embodiments. The semiconductor package of FIGS. 5A and 5B may include and/or may be similar in many respects to the semiconductor package described above with reference to FIGS. 1A to 4, and may include additional features not mentioned above. Consequently, repeated descriptions of the semiconductor package described above with reference to FIGS. 1A to 4 may be omitted for the sake of brevity.

Referring to FIG. 5A, the edge region ER may be removed from the film substrate 100 of a semiconductor package M depicted in FIG. 1A. The edge region ER on the film substrate 100 may be removed by cutting in a reel state. The removal of the edge region ER on the film substrate 100 may eliminate the first cut parts 312 of the plurality of first connection patterns 310 on the edge region ER and the second cut parts 322 of the plurality of second connection patterns 320 on the edge region ER.

The edge region ER on the film substrate 100 may be removed such that only the chip region CR may remain on the film substrate 100. The edge region ER on the film substrate 100 may be removed to allow the semiconductor package M to include the semiconductor chip 200, the first connection parts 311 of the plurality of first connection patterns 310, the second connection parts 321 of the plurality of second connection patterns 320, the pluralities of first to third pads PD1 to PD3, the first to third lines 410 to 430, the protection pattern PP, the test lines TW, and the test patterns TP on the chip region CR of the film substrate 100.

Referring to FIG. 5B, a package module may include a plurality of semiconductor packages M, a circuit substrate 20, and a display panel 30.

The circuit substrate 20 may be disposed on a top surface of the film substrate 100. The circuit substrate 20 may be adjacent to one side of the film substrate 100. The circuit substrate 20 may be, for example, a printed circuit board (PCB) or a flexible printed circuit board (FPCB). In an embodiment, an input connector may be interposed between the circuit substrate 20 and the connection parts 311 of the plurality of first connection patterns 310 to electrically connect the circuit substrate 20 to the connection parts 311 of the plurality of first connection patterns 310. The circuit substrate 20 may be electrically connected to the semiconductor chip 200 through the plurality of first lines 410 and the connection parts 311 of the plurality of first connection patterns 310.

The display panel 30 may be disposed on the top surface of the film substrate

100. The display panel 30 may be adjacent to another side of the film substrate 100. In an embodiment, an output connector may be interposed between the display panel 30 and the second connection parts 321 of the plurality of second connection patterns 320 to electrically connect the display panel 30 to the connection parts 321 of the plurality of second connection patterns 320. The display panel 30 may be electrically connected to the semiconductor chip 200 through the connection parts 321 of the plurality of second connection patterns 320, the plurality of second lines 420, and the plurality of third lines 430.

The semiconductor chip 200 may be supplied with signals from the circuit substrate 20 through the plurality of first lines 410 and the first connection parts 311 of the plurality of first connection patterns 310. The semiconductor chip 200 may include driving integrated circuits (e.g., gate driving integrated circuits and/or data driving integrated circuits), and may generate driving signals (e.g., gate driving signals and/or data driving signals). The driving signals generated from the semiconductor chip 200 may be supplied through the connection parts 321 of the plurality of second connection patterns 320, the plurality of second lines 420, and the plurality of third lines 430 to a gate line and/or a data line of the display panel 30. That is, the display panel 30 may operate based on the driving signals supplied by the semiconductor chip 200.

In a semiconductor package and a package module, according to some embodiments of the present disclosure, a test pattern may be separated to an outside, and thus a test line may extend long. Thus, it may be possible to alleviate electromagnetic interference (EMI) and electrostatic discharge (ESD) and to improve electrical properties of the semiconductor package, when compared to a related semiconductor package.

Although the present disclosure has been described in connection with the some embodiments of the present disclosure illustrated in the accompanying drawings, it is to be understood by one of ordinary skill in the art that variations in form and detail may be made therein without departing from the spirit and essential feature of the present disclosure. The above disclosed embodiments should thus be considered illustrative and not restrictive.

What is claimed is:

1. A semiconductor package, comprising:
a film substrate;
a plurality of first connection patterns disposed in a first direction on the film substrate;
a plurality of second connection patterns disposed in the first direction on the film substrate;
a semiconductor chip between the plurality of first connection patterns and the plurality of second connection patterns;
a protection pattern on the film substrate and at least partially surrounding the semiconductor chip;
a plurality of pads between the film substrate and the semiconductor chip;
a test pattern between the film substrate and the protection pattern;
a plurality of first lines respectively coupled with the plurality of first connection patterns;
a plurality of second lines respectively coupled with the plurality of second connection patterns; and
a test line extending from a line of the plurality of second lines and coupled with the test pattern,
wherein the test line comprises:
a first part between the film substrate and the semiconductor chip, the first part being coupled with the line of the plurality of second lines; and
a second part coupling the first part with the test pattern.

2. The semiconductor package of claim 1, wherein the first part has a loop shape.

3. The semiconductor package of claim 1, wherein the plurality of pads comprises:
a plurality of first pads respectively coupled with the plurality of first lines;
a plurality of second pads spaced apart in the first direction from the plurality of first pads; and
a plurality of third pads spaced apart in a second direction from the plurality of first pads, the second direction intersecting the first direction,
wherein the first part of the test line is between a first pad of the plurality of first pads and a second pad of the plurality of second pads, and
wherein the first part of the test line is between a fourth pad of the plurality of second pads and a third pad of the plurality of third pads.

4. The semiconductor package of claim 3, wherein the plurality of second lines comprises:
a first output line coupled with the second pad of the plurality of second pads; and
a second output line coupled with the third pad of the plurality of third pads, and
wherein the first output line is coupled with the first part of the test line.

5. The semiconductor package of claim 4, wherein the second part of the test line is between a first line of the plurality of first lines and a second line of the plurality of second lines, and
wherein the first line and the second line are adjacent to each other.

6. The semiconductor package of claim 3, wherein the first part of the test line comprises:
a first straight portion extending in the first direction;
a second straight portion extending in the second direction; and
a corner portion coupling the first straight portion with the second straight portion.

7. The semiconductor package of claim 6, wherein the first straight portion is between the second pad of the plurality of second pads and the third pad of the plurality of third pads.

8. The semiconductor package of claim 6, wherein the second straight portion comprises a plurality of second straight portions,
wherein the plurality of second straight portions comprises a first connection segment and a second connection segment,
wherein the first connection segment is coupled with a second line of the plurality of second lines, and
wherein the second connection segment is coupled with the second part of the test line.

9. The semiconductor package of claim 8, wherein the second connection segment is between the first pad of the plurality of first pads and the second pad of the plurality of second pads.

10. The semiconductor package of claim 1, wherein the second part of the test line is between the film substrate and the protection pattern.

11. The semiconductor package of claim 1, wherein the second part of the test line comprises:
a plurality of straight portions extending in at least one of the first direction or a second direction that intersects the first direction; and
a plurality of corner portions coupling the plurality of straight portions with each other.

12. The semiconductor package of claim 1, wherein the plurality of pads comprises:
a plurality of first pads respectively coupled with the plurality of first lines; and
a plurality of second pads respectively coupled with the plurality of second lines,
wherein the plurality of first pads and the plurality of second pads are spaced apart from each other in a second direction that intersects the first direction, and
wherein the first part of the test line is between a first pad of the plurality of first pads and a second pad of the plurality of second pads.

13. The semiconductor package of claim 3, wherein the plurality of second pads comprise:
an inner pad adjacent to the first pad of the plurality of first pads;
an outer pad adjacent to a sidewall of the semiconductor chip; and
an extension pad between the inner pad and the outer pad, and
wherein a second line of the plurality of second lines is in contact with the extension pad and is coupled with the test line.

14. The semiconductor package of claim 13, wherein a first distance between the first pad of the plurality of first pads and the inner pad is greater than a second distance between the inner pad and the extension pad.

15. The semiconductor package of claim 13, wherein the second part has a crooked shape between the first pad of the plurality of first pads and the inner pad.

16. A semiconductor package, comprising:
a film substrate comprising a plurality of sprocket holes;
a plurality of first connection patterns disposed in a first direction on the film substrate;
a plurality of second connection patterns disposed in the first direction on the film substrate;
a semiconductor chip between the plurality of first connection patterns and the plurality of second connection patterns;
a protection pattern on the film substrate and at least partially surrounding the semiconductor chip;
a plurality of pads between the film substrate and the semiconductor chip;
a test pattern between the film substrate and the protection pattern;
a plurality of first lines respectively coupled with the plurality of first connection patterns;
a plurality of second lines respectively coupled with the plurality of second connection patterns; and
a test line extending from a line of the plurality of second lines and coupled with the test pattern,
wherein the test line is coupled with:
the line of the plurality of second lines between the film substrate and the semiconductor chip, and
the test pattern between the film substrate and the protection pattern, and
wherein the plurality of sprocket holes are aligned along a second direction that intersects the first direction.

17. The semiconductor package of claim 16, wherein the test pattern is between the plurality of first lines and the plurality of second lines.

18. The semiconductor package of claim 16, further comprising:
a third line coupling the plurality of first connection patterns with the plurality of second connection patterns,
wherein the test pattern faces the third line.

19. The semiconductor package of claim 16, wherein the plurality of pads comprises:
a plurality of first pads respectively coupled with the plurality of first lines;
a plurality of second pads spaced apart in the first direction from the plurality of first pads; and
a plurality of third pads spaced apart in a second direction from the plurality of first pads, the second direction intersecting the first direction,
wherein the plurality of second lines comprises:
a first output line in contact with a second pad of the plurality of second pads; and
a second output line in contact with a third pad of the plurality of third pads,
wherein the test line comprises:
a first part coupled with the second output line; and
a second part coupled with the test pattern,
wherein the first part at least partially overlaps the semiconductor chip, and
wherein the second part does not overlap the semiconductor chip.

20. A package module, comprising:
a circuit substrate;
a display panel spaced apart from the circuit substrate; and
a plurality of semiconductor packages between the circuit substrate and the display panel, the plurality of semiconductor packages electrically coupling the circuit substrate with the display panel,
wherein each package of the plurality of semiconductor packages comprises:
a film substrate comprising a sprocket hole;
a first connection pattern coupled with the circuit substrate;
a second connection pattern coupled with the display panel;
a semiconductor chip on the film substrate;
a protection pattern on the film substrate and at least partially surrounding the semiconductor chip;
a plurality of pads between the film substrate and the semiconductor chip;
a test pattern between the film substrate and the protection pattern;
a first line coupled with the first connection pattern;
a second line coupled with the second connection pattern; and
a test line extending from the second line and coupled with the test pattern,
wherein the test line comprises:
a first part at least partially overlapping the semiconductor chip; and
a second part between the first line and the second line, and
wherein the first line and the second line are adjacent to each other.
